(19) United States
(12) Patent Application Publication
(10) Pub. No.: US 2019/0337273 A1
(43) Pub. Date: Nov. 7, 2019

(54) TRANSPARENT STACK STRUCTURE

(71) Applicant: DONGWOO FINE-CHEM CO., LTD., Jeollabuk-do (KR)

(72) Inventors: Myung Young AN, Incheon (KR); Sung Woo YU, Seoul (KR); Geo San LIM, Seoul (KR)

(21) Appl. No.: 16/515,732

(22) Filed: Jul. 18, 2019

Related U.S. Application Data
(63) Continuation of application No. PCT/KR2018/000990, filed on Jan. 23, 2018.

(30) Foreign Application Priority Data
Jan. 31, 2017 (KR) 10-2017-0013680

(51) Int. Cl. B32B 27/08; G02B 5/30; H05K 1/11; B32B 27/32

(52) U.S. Cl. CPC B32B 27/08; B32B 27/32; H05K 1/118; G02B 5/30

(57) ABSTRACT

A transparent stack structure includes a substrate and a hard coating layer stacked on the substrate. Compressive modulus and elastic restoration of the hard coating layer and the substrate satisfy Formula 1. Mechanical strength may be obtained from the substrate, and flexible and elastic properties may be enhanced by the hard coating layer so that cracks may be prevented when being folded or bent.

### CROSS REFERENCE TO RELATED APPLICATIONS AND CLAIM OF PRIORITY

The present application is a continuation application to International Application No. PCT/KR2018/000990 with an International Filing Date of Jan. 23, 2018, which claims the benefit of Korean Patent Application No. 10-2017-0013680, filed on Jan. 31, 2017, at the Korean Intellectual Property Office, the disclosures of which are incorporated by reference herein in their entirety.

### BACKGROUND

### 1. Field

The present invention relates to a transparent stack structure. More particularly, the present invention relates to a transparent structure capable of being utilized as an optical member, a sensor member or a display device member.

### 2. Description of the Related Art

Recently, an image display device capable of providing information with a display image is being actively developed. The display device includes a liquid crystal display (LCD) device, an organic light emitting display (OLED) device, a plasma display panel (PDP) device, a field emission display (FED) device, etc.

For example, a polarizing plate may be stacked on a display panel such as an LCD panel and an OLED panel so that optical properties and an image quality may be improved. Further, a touch sensor may be combined with the display panel so that display and information input functions may be implemented in the image display device.

Additionally, a thin flexible display capable that may be foldable or bendable is being actively developed. For example, a resin film including, e.g., polyimide may be used instead of a conventional glass substrate as a base substrate of the display panel in the flexible display.

However, as a conventional display device is replaced with the flexible display, a flexible property is also required in other components or structures combined with the display panel. For example, it may be desirable that properties of an optical member such as the polarizing plate, structures such as electrodes included in the touch sensor and a substrate for the polarizing plate or the touch sensor are developed to be applied to the flexible display.

For example, Korean Published Patent Application No. 2016-0120840 discloses a cover window for a flexible display, however, fails to disclose improving flexibility of other members except for the cover window.

### SUMMARY

According to an aspect of the present invention, there is provided a transparent stack structure having improved flexibility and mechanical stability.

According to an aspect of the present invention, there is provided a touch screen including the transparent stack structure.

According to an aspect of the present invention, there is provided polarizing plate including the transparent stack structure.

The above aspects of the present invention will be achieved by the following features or constructions:

(1) A transparent stack structure, comprising: a substrate; and a hard coating layer stacked on the substrate, wherein compressive modulus and elastic restoration of the hard coating layer and the substrate satisfy the following Formula 1:

$$\frac{{EIT}_{HC}}{{EIT}_{FILM}} < 1 \leq \frac{{nIT}_{HC}}{{nIT}_{FILM}} \qquad [ Formula 1 ]$$

In the Formula 1 above, EIT_{HC} is a compressive modulus of the hard coating layer, EIT_{FILM} is a compressive modulus of the substrate, nIT_{HC} is an elastic restoration of the hard coating layer and nIT_{FILM} is an elastic restoration of the substrate.

(2) The transparent stack structure according to the above (1), wherein the substrate includes a cyclo olefin polymer (COP) film.

(3) The transparent stack structure according to the above (1), wherein the hard coating layer is formed from a hard coating composition including a photo-curable oligomer, a photo-curable monomer, a photo-initiator and a solvent.

(4) The transparent stack structure according to the above (1), wherein a ratio of the compressive modulus of the hard coating layer relative to the compressive modulus of the substrate (EIT_{HC}/EIT_{FILM}) is 0.9 or less.

(5) The transparent stack structure according to the above (1), wherein a ratio of the elastic restoration of the hard coating layer relative to the elastic restoration of the substrate (nIT_{HC}/nIT_{FILM}) exceeds 1.

(6) The transparent stack structure according to the above (1), wherein a change ratio of break elongation (ΔFE) defined by the following Formula 2 is 30% or more:

$$Δ FE ( \% ) = \frac{{L}_{f} - {L}_{0}}{{L}_{0}} \times 100 \qquad [ Formula 2 ]$$

In the Formula 2 above, L_{f} is a break elongation of the transparent stack structure after forming the hard coating layer, and L₀ is a break elongation of the substrate before forming the hard coating layer.

(7) The transparent stack structure according to the above (1), wherein the hard coating layer includes a first hard coating layer and a second hard coating layer formed on an upper surface and a lower surface of the substrate, respectively.

(8) The transparent stack structure according to the above (1), wherein the transparent stack structure includes a planar portion and a bent portion from the planar portion.

(9) A touch screen including the transparent stack structure according to any one of the above (1) to (8).

(10) The touch screen according to the above (9), further comprising a sensing electrode formed directly on the hard coating layer.

(11) A polarizing plate including the transparent stack structure according to any one of the above (1) to (8).

(12) The polarizing plate according to the above (11), further comprising: a polarizer; and an adhesive layer attaching one surface of the polarizer to the transparent stack structure.

According to exemplary embodiments as described above, the transparent stack structure may include the hard coating layer formed on the substrate, and the substrate and the hard coating layer may satisfy a predetermined relation of a compressive modulus, an elastic restoration and a break elongation. Thus, desired flexible and elastic properties may be obtained through the hard coating layer while also obtaining mechanical strength through the substrate so that cracks may be prevented when being bent or folded.

The transparent stack structure may be applied to an image display device, e.g., a flexible display. For example, the transparent stack structure may serve as a substrate film of a polarizing plate, a touch screen, etc., so that the image display device having improved crack-resistance even when being folded may be achieved.

### BRIEF DESCRIPTION OF THE DRAWINGS

FIG. 1 is a cross-sectional view illustrating a transparent stack structure in accordance with exemplary embodiments of the present invention;

FIG. 2 is a cross-sectional view illustrating a transparent stack structure in accordance with exemplary embodiments of the present invention;

FIG. 3 is a cross-sectional view illustrating a touch screen in accordance with exemplary embodiments of the present invention;

FIG. 4 is a cross-sectional view illustrating a polarizing plate in accordance with exemplary embodiments of the present invention; and

FIG. 5 is a schematic view illustrating a transparent stack structure applied to an image display device including a bent portion.

### DETAILED DESCRIPTION

In a transparent stack structure according to exemplary embodiments of the present invention, a stack structure of a substrate and a hard coating layer which may satisfy a predetermined relation of a compressive modulus, an elastic restoration and/or a break elongation is provided. Accordingly, a transparent substrate having improved crack-resistance and adhesion when being bent or folded may be provided, and a flexible display having improved reliability may be fabricated using the transparent substrate.

Hereinafter, the present invention will be described in detail with reference to the accompanying drawings. However, those skilled in the art will appreciate that such embodiments described with reference to the accompanying drawings are provided to further understand the spirit of the present invention and do not limit subject matters to be protected as disclosed in the detailed description and appended claims.

Transparent Stack Structure

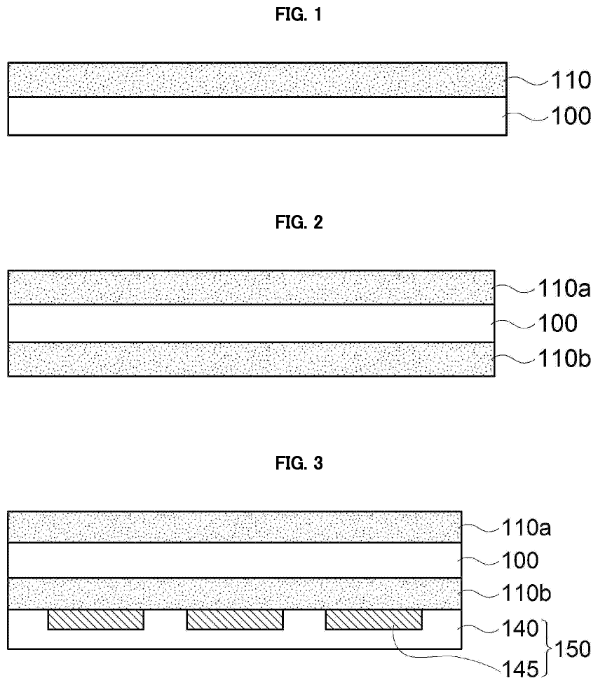

FIGS. 1 and 2 are cross-sectional views illustrating transparent stack structures in accordance with exemplary embodiments of the present invention.

The transparent stack structure may be inserted in an image display device such as an OLED device, an LCD device, etc., and may serve as a base substrate of various optical, circuit or sensing members.

Referring to FIG. 1, the transparent stack structure may include a substrate 100 and a hard coating layer 110 formed on the substrate 100.

The substrate 100 may include a supporting layer or a film-type substrate for forming the hard coating layer 110 or components and structures of a display device. For example, the substrate 100 may include a transparent polymer material. Examples of the polymer may include cyclo olefin polymer (COP) that may be synthesized from a cyclic monomer such as norbornene, polyethylene terephthalate (PET), polyacrylate (PAR), polyetherimide (PEI), polyethylene napthalate (PEN), polyphenylene sulfide (PPS), polyallylate, polyimide (PI), cellulose acetate propionate (CAP), polyethersulfone (PES), cellulose triacetate (TAC), polycarbonate (PC), cyclo olefin copolymer (COC), polymethylmethacrylate (PMMA), or the like. In an embodiment, a COP film may be used as the substrate 100 in consideration of transparency and strength.

A thickness of the substrate 100 may be, e.g., in a range from 4.5 to 60 μm. Preferably, the thickness of the substrate 100 may be in a range from 5 to 40 μm from an aspect of reducing a stress when being folded. If the thickness of the substrate 100 is less than 5 μm, tension and wrinkles generated during a fabrication may not be easily controlled due to an excessive small thickness. If the thickness of the substrate 100 exceeds about 40 μm, the stress may be excessively increased when being bent to cause fractures of the substrate 100.

The hard coating layer 110 may be formed by coating a hard coating composition on the substrate 100 and performing a photo-curing. The hard coating composition may include a photo-curable oligomer and/or monomer, a photo-initiator and a solvent.

The photo-curable oligomer may include (meth)acrylate oligomer, e.g., may include at least one of epoxy (meth)acrylate, urethane (meth)acrylate or polyester (meth)acrylate. For example, urethane (meth)acrylate and polyester (meth)acrylate may be used together, or two types of polyester (meth)acrylate may be used together.

Urethane (meth)acrylate may be prepared by reacting a multi-functional (meth)acrylate having a hydroxyl group in a molecule and a compound having an isocyanate group by a method widely known in the related art. The multi-functional (meth)acrylate having the hydroxyl group may include, e.g., 2-hydroxyethyl (meth)acrylate, 2-hydroxyisopropyl (meth)acrylate, 4-hydroxybutyl (meth)acrylate, caprolactone ring-opened hydroxyacrylate, a mixture of pentaerythritol tri/tetra (meth)acrylate, dipentaerythritol penta/hexa (meth)acrylate, etc. These may be used alone or in a combination thereof.

The compound having the isocyanate group may include, e.g., 1,4-diisocyanatobutane, 1,6-diisocyanatohexane, 1,8-diisocyanantooctane, 1,12-diisocyanatododecane, 1,5-diisocyanato-2-methylpentane, trimethyl-1,6-diisocyanatohexane, 1,3-bis(isocyanatomethyl)cyclohexane, trans-1,4-cyclohexenediisocyanate, 4,4′-methylenebis(cyclohexylisocyanate), isophorone diisocyanate, toluene-2,4-diisocyanate, toluene-2,6-diisocyanate, xylene-1,4-diisocyanate, tetramethyl xylene-1,3-diisocyanate, 1-chloromethyl-2,4-diisocyanate, 4,4′-methylenebis(2,6-dimethylphenylisocyanate), 4,4′-oxybis(phenylisocyanate), tri-functional isocyanate derived from hexamethylenediisocynate, and trimethanepropanol adduct tolenediisocyanate.

Polyester (meth)acrylate may be prepared by reacting polyester polyol with acrylic acid by a method widely known in the related art. The polyester (meth)acrylate may include, e.g., polyester acrylate, polyester diacrylate, polyester tetraacrylate, polyester hexaacrylate, polyester pentaerythritol triacrylate, polyester pentaerythritol tetraacrylate, polyester pentaerythritol hexaacrylate, etc. These may be used alone or in a combination thereof.

The photo-curable monomer may include, a monomer having an unsaturated group, e.g., a (meth)acryloyl group, a vinyl group, a styryl group, an allyl group as a photo-curable functional group in a molecule without a particular limitation. Preferably, a monomer having the (meth)acryloyl group may be used as the photo-curable monomer.

The monomer having the (meth)acryloyl group may include, e.g., neopentyl glycol acrylate, 1,6-hexanediol (meth)acrylate, propyleneglycol di(meth)acrylate, triethyleneglycol di(meth)acrylate, dipropyleneglycol di(meth)acrylate, polyethyleneglycol di(meth)acrylate, polypropyleneglycol di(meth)acrylate, trimethylolpropane tri(meth)acrylate, trimethylolethane tri(meth)acrylate, 1,2,4-cyclohexane tetra(meth)acrylate, pentaglycerol tri(meth)acrylate, pentaerythritol tetra(meth)acrylate, pentaerythritol tri(meth)acrylate, dipentaerythritol tri(meth)acrylate, pentaerythritol penta(meth)acrylate, dipentaerythritol tetra(meth)acrylate, dipentaerythritol hexa(meth)acrylate, tripentaerythritol tri(meth)acrylate, tripentaerythritol hexa(meth)acrylate, bis(2-hydroxyethyl)isocyanurate di(meth)acrylate, hydroxyethyl (meth)acrylate, hydroxypropyl (meth)acrylate, hydroxybutyl (meth)acrylate, isooctyl (meth)acrylate, isodecyl (meth)acrylate, stearyl (meth)acrylate, tetrahydrofurfuryl (meth)acrylate, phenoxyethyl (meth)acrylate, isobomeol (meth)acrylate, etc. These may be used alone or in a combination thereof.

In some embodiments, the hard coating composition may further include a UV-curable silicon resin having (meth)acryl group. For example, polydimethyl siloxane containing an acryloxy propyl group, polydimethyl siloxane containing methacryloxy propyl group, etc., may be added.

In some embodiments, the hard coating composition may further include, e.g., a particle having an average diameter of about 0.5 μm or less for improving an anti-blocking property.

The particle may include an organic-based particle or an inorganic-based particle. The organic-based particle may be formed of a resin material such as acryl, olefin, polyether, polyester, urethane, silicone, polysilane, polyimide, etc.

The inorganic-based particle may include silica, alumina, titania, zeolite, mica, synthesized mica, calcium oxide, zirconium oxide, zinc oxide, magnesium fluoride, smectite, synthesized smectite, vermiculite, ITO (indium oxide/tin oxide), ATO (antimony oxide/tin oxide), tin oxide, indium oxide, antimony oxide, etc.

The photo-initiator may include, e.g., any compounds capable of initiating a polymerization of the photo-curable compound through generating ions, Lewis acids or radicals by an active energy ray such as visible light, ultraviolet, X-ray or electron beam. Examples of the photo-initiator may include an aromatic diazonium salt, an onium salt such as an aromatic iodonium salt or an acetophenone-based compound, a benzoin-based compound, a benzophenone-based compound, a thioxantone-based compound, etc.

The solvent may include an alcohol-based solvent (methanol, ethanol, isopropanol, butanol, propylene glycol methoxy alcohol, etc.), a ketone-based solvent (methylethyl ketone, methylbutyl ketone, methylisobutyl ketone, diethyl ketone, dipropyl ketone, etc.), an acetate-based solvent (methyl acetate, ethyl acetate, butyl acetate, propylene glycol methoxy acetate, etc.), a cellosolve-based solvent (methyl cellosolve, ethyl cellosolve, propyl cellosolve, etc.), a hydrocarbon-based solvent (normal hexane, normal heptane, benzene, toluene, xylene, etc.), etc. These may be used alone or in a combination thereof.

The hard coating composition may further include additives widely used in the related art, e.g., an anti-oxidant, a UV absorber, a light stabilizer, a thermal polymerization inhibitor, a leveling agent, a lubricant, etc.

For example, the hard coating composition may be coated on the substrate using a die coater, an air knife, a reverse roll, a spray, a blade, a casting, a gravure, a micro gravure, a spin coating, etc. The coated composition may be vaporized and dried at a temperature of, e.g., 30 to 150° C., and may be cured by irradiating a UV light. An irradiation amount of the UV light may be about 0.01 to 10 J/cm².

In exemplary embodiments, a thickness of the hard coating layer 110 may be in a range from about 0.5 to 10 μm, preferably about 1 to 5 μm. Within this range, desired elastic, tensile, elongation properties, etc., of the hard coating layer 110 may be easily obtained. For example, if the thickness of the hard coating layer 110 is less than about 1 μm, functions and properties of the hard coating layer may not be sufficiently implemented. If the thickness of the hard coating layer 110 exceeds about 5 μm, a folding stress may be increased due to a thickness increase to cause wrinkles even though fractures may be prevented.

According to exemplary embodiments of the present inventive concepts, the hard coating layer 110 may be more flexible than the substrate 100, and an elastic restoration of the hard coating layer 100 may be equal to or greater than that of the substrate 100. Thus, a ratio of an elastic restoration of the hard coating layer 110 (nIT_{HC}) relative to the elastic restoration of the substrate 100 (nIT_{FILM}) may be 1 or more.

In some embodiments, a compressive modulus of the hard coating layer 110 (EIT_{HC}) may be smaller than a compressive modulus of the substrate 100 (EIT_{FILM}).

For example, the compressive modulus and the elastic restoration of the hard coating layer 110 and the substrate 100 may satisfy the following Formula 1.

$$\frac{{EIT}_{HC}}{{EIT}_{FILM}} < 1 \leq \frac{{nIT}_{HC}}{{nIT}_{FILM}} \qquad [ Formula 1 ]$$

As described above, e.g., the COP-based substrate 100 may have relatively high strength and hardness, however, may have insufficient flexibility and high brittleness. Thus, when the substrate 100 is solely used as a base film of a flexible display, cracks may be generated during transformation by folding or bending, and mechanical failure may be caused.

However, according to exemplary embodiments of the present invention, the hard coating layer 110 having relatively high flexibility and elastic restoration may be formed on the substrate 100 so that degradation of mechanical durability due to high brittleness and hardness of the substrate 100 may be avoided or reduced. Thus, the transparent stack structure having entirely improved flexible and anti-crack properties may be obtained.

In an embodiment, the ratio of the elastic restoration of the hard coating layer 110 relative to the elastic restoration of the substrate 100 (nIT_{HC}/nIT_{FILM}) may be greater than 1. Further, a ratio of the compressive modulus of the hard coating layer 110 relative to the compressive modulus of the substrate 100 may be about 0.9 or less. In this case, flexible and anti-crack properties of the transparent stack structure may be further enhanced.

Additionally, the hard coating layer 110 may be formed on the substrate 100 so that an elongation or a break elongation of the transparent stack structure may be improved, and thus a folding property of the transparent stack structure may be further improved. Therefore, when a display device includes a bent portion, the transparent stack structure may be disposed throughout a planar portion and the bent portion, and cracks and delamination at the bent portion may be prevented.

In some embodiments, a change ratio of the break elongation in the transparent stack structure including the hard coating layer may be about 30% or more. In an embodiment, the change ratio of the break elongation in the transparent stack structure may be about 40% or more.

For example, the change ratio of the break elongation (ΔFE) may be defined by the following Formula 2.

$$Δ FE ( \% ) = \frac{{L}_{f} - {L}_{0}}{{L}_{0}} \times 100 \qquad [ Formula 2 ]$$

(L_{f}: Break elongation after forming the hard coating layer, L₀: Break elongation of the substrate before forming the hard coating layer)

The break elongation may be measured by a tensile test method of a film or a sheet based on a standard of, e.g., ASTM D882 or ISO 527-3.

As described above, tensile and elongation properties of the transparent stack structure may be improved by the addition of the hard coating layer 110 so that mechanical stability of, e.g., a flexible display may be obtained at the bent portion.

The elastic restoration, the compressive modulus and/or the break elongation of the transparent stack structure or the hard coating layer 110 may be controlled by, e.g., adjusting amounts of ingredients in the hard coating composition for forming the hard coating layer 110 (e.g., amounts of the photo-curable oligomer or the photo-initiator) and a degree of crosslinking in the curing process. The degree of crosslinking may be changed by, e.g., adjusting an amount or a time of the UV irradiation.

In some embodiments, the hard coating layer 110 may serve as an anti-blocking layer. For example, if the transparent stack structure is fabricated in a winding form on a roller, an adhesion to the roller or a self-adhesion in the transparent stack structure may be prevented by the hard coating layer 110.

In exemplary embodiments, a water contact angle of the hard coating layer 110 may be in a range from about 60 to 110 degree (°). A surface roughness (Rz) of the hard coating layer 110 may be in a range from about 1 to 5 μm. The surface properties of the hard coating layer 110 may be controlled within this range so that an anti-blocking property may be obtained and the transparent stack structure may be easily applied to a display device.

Referring to FIG. 2, hard coating layers may be stacked on both surfaces of the substrate 100. For example, a first hard coating layer 110a and a second hard coating layer 110b may be formed on an upper surface and a lower surface of the substrate 100, respectively.

As illustrated in FIG. 2, the hard coating layers may cover upper and lower portions of the substrate 100 so that flexible and anti-crack properties of the transparent stack structure may be obtained by the hard coating layers 110b and 110b covering the substrate 100 while achieving mechanical strength of the transparent stack structure from the substrate 100.

Touch Screen/Polarizing Plate

According to exemplary embodiments of the present invention, a touch screen and a polarizing plate including the transparent stack structure as described with reference to FIGS. 1 and 2 are provided.

FIG. 3 is a cross-sectional view illustrating a touch screen in accordance with exemplary embodiments of the present invention.

Referring to FIG. 3, the transparent stack structure, e.g., as described with reference to FIG. 2 may be used as a substrate film in the touch screen, and a touch sensor layer 150 may be stacked on the transparent stack structure. The transparent stack structure may include, e.g., the substrate 100, and the first and second hard coating layers 110a and 110b formed on upper and lower surfaces of the substrate 100, respectively.

The touch sensor layer 150 may include sensing electrode 145. A touch input may be detected by the sensing electrode 145 to induce a capacitance change, and a plurality of the sensing electrodes 145 may be formed. The sensing electrode 145 may be formed on one surface of the transparent stack structure. In an embodiment, as illustrated in FIG. 3, the touch sensor layer 150 or the sensing electrode 145 may be formed on the second hard coating layer 110b, and the first hard coating layer 110a may be disposed toward, e.g., a viewer side of an image display device.

In an embodiment, the sensing electrode 145 may be directly formed on a surface of the second hard coating layer 110b. In an embodiment, the sensing electrode 145 may be combined with the second hard coating layer 110b via an insulation member such as a protective layer, an adhesive layer, etc.

For example, the touch screen may be disposed below a window substrate of the image display device, and a touch signal input by a user on the first hard coating layer 110a may be converted into an electrical signal by the sensing electrode 145.

In some embodiments, the touch sensor layer 150 may be operated by a mutual-capacitance type. In this case, the sensing electrodes 145 may include first sensing electrodes and second sensing electrodes which may be arranged in different directions crossing each other (e.g., X-direction and Y-direction). In some embodiments, the touch sensor layer 150 may further include an insulation layer for insulating the first and second sensing electrodes from each other. A bridge electrode electrically connecting unit electrodes included in the first sensing electrodes or the second sensing electrodes may be also included.

In some embodiments, the touch sensor layer 150 may be operated by a self-capacitance type. In this case, the sensing electrodes 145 may include unit island electrodes that may be separated from each other. Peripheral wirings and pad electrodes electrically connected to the sensing electrodes 145 may be further formed on the second hard coating layer 110b.

For example, a protective layer 140 covering the sensing electrodes 145 may be formed on the second hard coating layer 110b. The sensing electrode 145 may include, e.g., a transparent conductive material. Examples of the transparent conductive material may include indium tin oxide (ITO), indium zinc oxide (IZO), zinc oxide (ZnO), indium zinc tin oxide (IZTO), cadmium tin oxide (CTO), a metal wire, etc. These may be used alone or in a combination thereof. In an embodiment, the sensing electrode 145 may include ITO. Non-limiting examples of a metal used in the metal wire may include silver, gold, aluminum, copper, iron, nickel, titanium, tellurium, chromium or an alloy thereof.

The protective layer 140 may include, e.g., an inorganic insulation material such as silicon oxide or a transparent organic material such as an acryl-based resin.

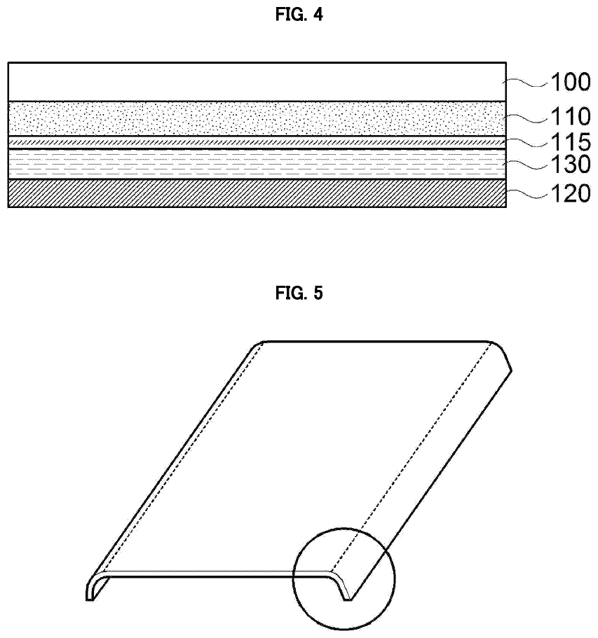

FIG. 4 is a cross-sectional view illustrating a polarizing plate in accordance with exemplary embodiments of the present invention.

Referring to FIG. 4, the polarizing plate may include a transparent stack structure according to exemplary embodiments and a polarizer 130 combined with the transparent stack structure. As described above, the transparent stack structure may include a stack structure of the substrate 100 and the hard coating layer 110.

In some embodiments, the polarizer 130 may be attached or adhered to the transparent stack structure via an adhesive layer 115. For example, the polarizer 130 may be attached to the hard coating layer 110 via the adhesive layer 115. The adhesive layer 115 may contact an upper surface of the polarizer 130 and a lower surface of the hard coating layer 110.

The polarizer 130 may be a film including a polymer resin and a dichroic material. The polymer resin may include, e.g., a polyvinyl alcohol (PVA)-based resin. The PVA-based resin may be preferably obtained by a saponification of a polyvinyl acetate resin. The polyvinyl acetate resin may include polyvinyl acetate as a homopolymer of vinyl acetate, a copolymer of vinyl acetate and other monomers that may be copolymerized with vinyl acetate. The monomer copolymerizable with vinyl acetate may include an unsaturated carboxylic acid monomer, an unsaturated sulfonic acid monomer, an olefin monomer, a vinyl ether monomer, an ammonium group-containing acrylamide monomers, or the like.

The PVA-based resin may include a modified resin, for example, aldehyde-modified polyvinylformal, polyvinylacetal, or the like.

In some embodiments, the polarizer 130 may be a liquid crystal layer including a liquid crystal compound oriented in one direction.

A material of the adhesive layer 115 may not be specifically limited, and may be selected in consideration of obtaining an adhesion with the transparent stack structure and the polarizer, and proper viscoelasticity. For example, the adhesive layer 115 may include an acrylate-based pressure sensitive adhesive (PSA) material or optically clear adhesive (OCA) material.

A protective film 120 may be stacked or attached on a lower surface of the polarizer 130. The protective film 120 may include, e.g., a polyester resin such as polyethylene terephthalate, polyethylene isophthalate, polyethylene naphthalate, polybutylene terephthalate, etc.; a cellulose resin such as diacetyl cellulose, triacetyl cellulose, etc.; a polycarbonate resin; an acryl resin such as polymethyl (meth)acrylate, polyethyl (meth)acrylate, etc.

In some embodiments, the transparent stack structure may include the first and second hard coating layers 110a and 110b as illustrated in FIG. 2. In this case, the polarizer 130 may be attached to the second hard coating layer 110b, and the first hard coating layer 110a may face the polarizer 130 with respect to the substrate 100. When the polarizing plate is applied to an image display device, the first hard coating layer 110a may be disposed toward a viewer side.

The transparent stack structure may include a stack structure of the substrate 100 and the hard coating layers 110a and 110b which satisfy relations of the elastic restoration, the compressive modulus and the break elongation. Thus, desired anti-crack and flexible properties may be achieved by the hard coating layers 110a and 110b while obtaining mechanical reliability such as an anti-shock property from the substrate 100.

Therefore, the touch sensor or the polarizing plate having mechanical properties for being applied to a flexible display may be implemented on the transparent stack structure.

Image Display Device

According to exemplary embodiments of the present invention, an image display device including the transparent stack structure as described above is provided.

The transparent stack structure may be combined with a display panel included in an OLED device, an LCD device, etc. The display panel may include a pixel circuit including a thin film transistor (TFT) arrange don a substrate, and a pixel unit or a light-emitting unit electrically connected to the pixel circuit.

For example, the touch screen as described with reference to FIG. 3 may be disposed on the display panel. Further, the polarizing plate as described with reference to FIG. 4 may be disposed on the display panel. In some embodiments, a stack structure of a touch screen-polarizing plate-transparent stack structure may be disposed on the display panel.

A window substrate exposed to an outside of the image display device may be disposed on the transparent stack structure.

The image display device may be a flexible display, and cracks and delamination may be prevented while being bent by the transparent stack structure.

FIG. 5 is a schematic view illustrating a transparent stack structure applied to an image display device including a bent portion.

The image display device may include a bent portion at a peripheral portion (e.g., both lateral portions). In this case, as described in FIG. 5, the transparent stack structure may also include a bent portion (indicated as a circle) downwardly from a planar portion that may be substantially flat. Cracks at the bent portion may be suppressed by improved elongation properties by the hard coating layer according to exemplary embodiments.

Hereinafter, preferred embodiments are proposed to more concretely describe the present invention. However, the following examples are only given for illustrating the present invention and those skilled in the related art will obviously understand that these examples do not restrict the appended claims but various alterations and modifications are possible within the scope and spirit of the present invention. Such alterations and modifications are duly included in the appended claims.

### Examples and Comparative Examples

A COP film manufactured by Zeon Co., Ltd. (thickness: 23 μm) was used as a substrate, and a hard coating composition was coated on upper and lower surfaces of the substrate and UV-cured to form hard coating layers (thickness: 2.5 μm). In the hard coating composition, a dendrimer acrylate (Miramer SP1106, Miwon Specialty Chemical Co., Ltd.), urethane hexaacrylate (Miramer PU620, Miwon Specialty Chemical Co., Ltd.) and polyester tetraacrylate (Miramer PS420, Miwon Specialty Chemical Co., Ltd.) as a photo-curable oligomer, pentaerythritol triacrylate (Miramer M340, Miwon Specialty Chemical Co., Ltd.) and polyethyleneglycol (400) diacrylate (Miramer M280, Miwon Specialty Chemical Co., Ltd.) as a photo-curable monomer, silica sol having a diameter of 50 nm as particles (MEK-ST-L, Nissan Chemical Co., Ltd.), 1-hydroxy cyclohexyl phenyl ketone (Irgacure 184, CIBA Co., Ltd.) as a photo-initiator and methyl ethyl ketone as a solvent were mixed.

Contents of the photo-curable oligomer, the photo-curable monomer and the photo-initiator in the hard coating composition and an amount of light irradiation in the UV-curing were adjusted to change a compressive modulus, an elastic restoration and a break elongation of the hard coating layer so that transparent stack structure samples of Examples and Comparative Example were prepared.

Comparative Example 2 was prepared as a single substrate member of the COP film.

Values of compressive modulus, elastic restoration and break elongation in Examples and Comparative Examples were measured (measurement device: Nano indentor), and ratios of compressive modulus, elastic restoration and break elongation between the substrate and hard coating layer were calculated. The results are shown in Table 1 below.

Values of compressive modulus, elastic restoration and break elongation in Comparative Example 2 were commonly used in the substrates of Examples 1 and 2, and Comparative Example 1.

Compressive modulus and elastic restoration were measured using HM-500 of Fisher Co., Ltd.) based on a standard of ISO-FDIS 14577-1 2013(E). Break elongation was measured using Autograph AG-X of Shimadzu Co., Ltd. Specifically, break elongation was measure based on a standard of ASTM D882 or ISO 527-3 for testing tensile properties of a film or a sheet.

TABLE 1

| | | | | Comparative |
|---|---|---|---|---|
| | | | | Example 2 |
| | Example | Example | Comparative | (substrate |
| | 1 | 2 | Example 1 | only) |
| Compressive | 3797 | 3797 | 3797 | 3797 |
| Modulus of | | | | |
| Substrate | | | | |
| (EIT_{FILM})(MPa) | | | | |
| Compressive | 3254 | 3512 | 5701 | — |
| Modulus of Hard | | | | |
| Coating Layer | | | | |
| (EIT_{HC})(MPa) | | | | |
| Elastic Restoration | 37.8 | 37.8 | 37.8 | 37.8 |
| of Substrate | | | | |
| (nIT_{FILM})(%) | | | | |
| Elastic Restoration | 42.4 | 48.2 | 63.2 | — |
| of Hard Coating | | | | |
| Layer | | | | |
| (nIT_{HC})(%) | | | | |
| Break Elongation | 5.0 | 5.0 | 5.0 | 5.0 |
| of Substrate (%) | | | | |
| Break Elongation | 7.2 | 7.8 | 4.1 | — |
| after Forming Hard | | | | |
| Coating Layer (%) | | | | |
| EIT_{HC}/EIT_{FILM} | 0.857 | 0.925 | 1.501 | — |
| nIT_{HC}/nIT_{FILM} | 1.122 | 1.275 | 1.672 | — |
| Change Ratio of | 44 | 56 | −18 | — |
| Break Elongation | | | | |
| (%) | | | | |

### Experimental Example

(1) Evaluation of Anti-Crack Property

The transparent stack structure was cut by a size of 1 cm×1 cm to prepare a sample, and a bending test was performed 100,000 times with a radius of curvature of 2 mm. After the test, crack generation of the transparent stack structure was visually determined by the following standard.

◯: Cracks were not generated throughout an entire region of the sample.

Δ: Cracks were partially observed at an bent portion.

x: Cracks were expanded throughout an entire region of the sample.

(Cracks were generated: x, Cracks were not generated: 0)

(2) Evaluation of Adhesion

11 linear lines in each vertical direction and horizontal direction with a distance of 1 mm between neighboring lines were drawn on a coating surface of each hard coating layer of Examples 1 and 2 and Comparative Example 1 to form 100 squares, and then detachment tests were performed 3 times using a tape (CT-24, NICHIBAN Co., Ltd.).

An average value of 3 sets of 100 squares was calculated. An adhesion was measures by the following method.

i) Adhesion=n/100

ii) n: the number of squares that were not detached among all squares, 100: a total number of squares

When no square was detached, the adhesion was measured as 100/100.

(3) Evaluation of Anti-Blocking Property

Two samples were prepared from each transparent stack structure of Examples 1 and 2, and Comparative Example 1, and were pressed and attached to each other using a roller with 2 kg load. After 5 minutes, the anti-blocking property was evaluated by determining whether the two samples were detached from each other again as follows.

◯: Two samples were separated again

x: Two samples were completely attached and were not separated again

The results measured as described above are shown in Table 2 below.

TABLE 2

| | Anti-crack | | Anti-blocking |
|---|---|---|---|
| | property | Adhesion | property |
| Example 1 | ◯ | 100/100 | ◯ |
| Example 2 | ◯ | 95/100 | ◯ |
| Comparative | Δ | 70/100 | X |
| Example 1 | | | |
| Comparative | X | — | — |
| Example 2 | | | |

Referring to Table 2 above, the transparent stack structure of Examples satisfying Formula 1 as described above showed remarkably improved anti-crack property, adhesion and anti-blocking property compared to those in Comparative Examples. Specifically, the transparent stack structure of Example 1 having EIT_{HC}/EIT_{FILM} value of 0.9 or less showed improved adhesion (delamination resistance) compared to that in Example 2.

In Comparative Example 1 including the hard coating layer, cracks were partially generated at the bent portion. However, in Comparative Example 2 only having the substrate, cracks were propagated throughout an entire region of the film.

What is claimed is:

1. A transparent stack structure, comprising:
a substrate; and
a hard coating layer stacked on the substrate,
wherein compressive modulus and elastic restoration of the hard coating layer and the substrate satisfy the following Formula 1:
$$\frac{{EIT}_{HC}}{{EIT}_{FILM}} < 1 \leq \frac{{nIT}_{HC}}{{nIT}_{FILM}} \qquad [ Formula 1 ]$$
wherein, in the Formula 1, EIT_{HC} is a compressive modulus of the hard coating layer, EIT_{FILM} is a compressive modulus of the substrate, nIT_{HC} is an elastic restoration of the hard coating layer and nIT_{FILM} is an elastic restoration of the substrate.

2. The transparent stack structure according to claim 1, wherein the substrate includes a cyclo olefin polymer (COP) film.

3. The transparent stack structure according to claim 1, wherein the hard coating layer is formed from a hard coating composition including a photo-curable oligomer, a photo-curable monomer, a photo-initiator and a solvent.

4. The transparent stack structure according to claim 1, wherein a ratio of the compressive modulus of the hard coating layer relative to the compressive modulus of the substrate (EIT_{HC}/EIT_{FILM}) is 0.9 or less.

5. The transparent stack structure according to claim 1, wherein a ratio of the elastic restoration of the hard coating layer relative to the elastic restoration of the substrate (nIT_{HC}/nIT_{FILM}) exceeds 1.

6. The transparent stack structure according to claim 1, wherein a change ratio of break elongation (ΔFE) defined by the following Formula 2 is 30% or more:
$$Δ FE ( \% ) = \frac{{L}_{f} - {L}_{0}}{{L}_{0}} \times 100 \qquad [ Formula 2 ]$$
wherein, in the Formula 2 above, L_{f} is a break elongation of the transparent stack structure after forming the hard coating layer, and L₀ is a break elongation of the substrate before forming the hard coating layer.

7. The transparent stack structure according to claim 1, wherein the hard coating layer includes a first hard coating layer and a second hard coating layer formed on an upper surface and a lower surface of the substrate, respectively.

8. The transparent stack structure according to claim 1, wherein the transparent stack structure includes a planar portion and a bent portion from the planar portion.

9. A touch screen including the transparent stack structure according to any one of claim 1.

10. The touch screen according to claim 9, further comprising a sensing electrode formed directly on the hard coating layer.

11. A polarizing plate including the transparent stack structure according to claim 1.

12. The polarizing plate according to claim 11, further comprising:
a polarizer; and
an adhesive layer attaching a surface of the polarizer to the transparent stack structure.
